(19) United States
(12) Patent Application Publication
(10) Pub. No.: US 2025/0046563 A1
(43) Pub. Date: Feb. 6, 2025

(54) MAGNETIC FOCUSING DEVICE LOW ENERGY ION BEAMS

(71) Applicant: Axcelis Technologies, Inc., Beverly, MA (US)

(72) Inventors: Wilhelm Peter Platow, Newburyport, MA (US); Edward C. Eisner, Lexington, MA (US); Shu Satoh, Byfield, MA (US)

(21) Appl. No.: 18/362,429

(22) Filed: Jul. 31, 2023

(51) Int. Cl. H01J 37/141; H01J 37/21; H01J 37/244; H01J 37/317

(52) U.S. Cl. CPC H01J 37/141; H01J 37/21; H01J 37/244; H01J 37/3171; H01J 2237/0475; H01J 2237/141; H01J 2237/1415; H01J 2237/24585

(57) ABSTRACT

A magnetic focusing apparatus for focusing an ion beam has a first magnet pair, a first core having a first yoke and a pair of first pole members defining a pair of first poles. A second core has a second yoke and a pair of second pole members defining a pair of second poles. A first gap separates the pairs of first and second poles. First and second coils are respectively wound around the first and second cores. The pairs of first and second poles control a focus of the ion beam along a first plane based on a current, and the pairs of first and second poles define an exit trajectory of the ion beam along a second plane downstream of the first magnet pair. The exit trajectory does not angularly deviate along the second plane from an entrance trajectory upstream of the first magnet pair.

### FIELD

The present invention relates generally to ion implantation systems and methods, and more specifically to a focusing magnet configured for low energy ion beams that are susceptible to space-charge expansion.

### BACKGROUND

Ion implanters are conventionally utilized to place a specified quantity of dopants or impurities within workpieces or semiconductor wafers. In a typical ion implantation system, a dopant material is ionized, therein generating a beam of ions, generally referred to as an ion beam. The ion beam is directed at a surface of the workpiece to implant ions into the workpiece, wherein the ions penetrate the surface of the workpiece and form regions of desired conductivity therein. For example, ion implantation has particular use in the fabrication of transistors in semiconductor workpieces.

A typical ion implanter comprises an injector, a beamline assembly having a mass analysis apparatus for directing and/or filtering (e.g., mass resolving) ions within the ion beam, and a process chamber containing one or more workpieces to be treated. An ion source associated with the injector typically produces ions, whereby the ions are extracted from the ion source to form the ion beam. A desired ion species is selected to be implanted via an analyzing magnet, whereby the beamline further modifies the ion beam, including acceleration, deceleration, scanning, and/or angle control of the ion beam to define a final ion beam. The process chamber typically receives the final ion beam for implantation into the workpiece.

Magnets of various varieties are common in ion implantation systems. For example, an analyzing magnet described in patent U.S. Pat. No. 6,498,348 by Aitken is provided to mass analyze an ion beam after the ion beam has been extracted from an ion source. The analyzing magnet of Aitken employs an array of magnets or poles and a resolving aperture for mass analysis of an ion beam with elongated cross section (a so-called ribbon beam), wherein the mass analysis alters a trajectory of an ion beam based on various parameters of the ion beam, such as mass, energy, or charge. The mass analysis magnet comprises a set of coils wound around each of the poles provided therein, whereby a length of the mass analysis magnet is substantial in order to accommodate the respective coils. Such an arrangement of coils substantially lengthens the path of ion beam, thus increasing a size or footprint of the system in which it is disposed.

A magnetic lens device was proposed for mass analysis in patent U.S. Pat. No. 8,921,802 by White, whereby two “E-shaped blocks” are provided, wherein two coils rest within the special volume provided by two parallel recessed channels on the face of the E-shaped block. FIG. 1 illustrates a magnetic field orientation for a conventional E-lens 10, such as provided by White. As illustrated in FIG. 1, the conventional E-lens 10 comprises a coil 12 wrapped around a pole 14, whereby a magnetic field B is induced by electrical current through the coil. Such a conventional E-lens 10, however, does not produce a dipole field between the poles 14. Rather, the magnetic fields from the poles 14 oppose each other and are “oppositely magnetized”, thus creating a complicated field which twists an ion beam 16 as it passes therethrough.

### SUMMARY

The present disclosure provides a magnetic focusing device for an ion implantation system, wherein the magnetic focusing device is configured to control a height of a monochromatic ion beam of a single species in a vertical axis while providing substantially constant dimensions and angular orientation of the ion beam along a trajectory in a horizontal axis. The magnetic focusing device provided in the present disclosure, for example, is further amenable to scaling in order to provide increased horizontal widths of a scanned ion beam while maintaining a constant number of Amp-turns associated with a coil of the magnetic focusing device. The magnetic focusing device of the present disclosure, for example, is further suitable for both a scanned spot ion beam and a ribbon-shaped ion beam.

Accordingly, the following presents a simplified summary of the disclosure in order to provide a basic understanding of some aspects of the invention. This summary is not an extensive overview of the invention. It is intended to neither identify key or critical elements of the invention nor delineate the scope of the invention. Its purpose is to present some concepts of the invention in a simplified form as a prelude to the more detailed description that is presented later.

The present disclosure provides a magnetic focusing apparatus for focusing an ion beam, as well as various systems, such as an ion implantation system including the magnetic focusing apparatus. The ion beam, according to various examples, is considered to travel substantially in the z-axis in a cartesian coordinate system along a beam path, and can comprise any ion beam having a larger overall width (e.g., along the x-axis) than height (e.g., along the y-axis) when viewed along a path of the ion beam. The present disclosure, for example, contemplates a scanned ion beam (e.g., a scanned spot ion beam) as having a width equal to a scan length of the ion beam, thus defining a ribbon-like ion beam. Alternatively, the present disclosure contemplates other examples including a ribbon beam that has a larger width than height upon extraction.

In accordance with various example aspects of the present disclosure, a magnetic focusing apparatus is provided, wherein the magnetic focusing apparatus comprises a first magnet pair. The first magnet pair, for example, comprises a first core having a first yoke and a pair of first elongate pole members extending from the first yoke, thereby defining a first U-shape in the y-z plane extending along the x-axis. The pair of first elongate pole members, for example, generally define a pair of first poles, whereby each first pole is associated with a distal end of the respective first elongate pole member. In one example, a first coil is wound around the first core.

A second core, for example, is provided having a second yoke and a pair of second elongate pole members extending from the second yoke, thereby defining a second U-shape in the y-z plane extending along the x-axis. The pair of second elongate pole members, for example, generally define a pair of second poles at respective distal ends thereof. The pair of second poles, for example, are separated from the pair of first poles by a first gap configured to pass the ion beam therethrough. A second coil, for example, is further wound around the second core.

In one example, a current source is configured to selectively supply a current to the first coil and the second coil, respectively. The pair of first poles and the pair of second poles, for example, are thereby configured to control a focus of the ion beam along the y-z plane based on the current supplied to the respective first and second coils. The pair of first poles and the pair of second poles, for example, are further configured to define an exit trajectory of the ion beam along the x-z plane downstream of the first magnet pair. In accordance with the present disclosure, the exit trajectory of the ion beam does not angularly deviate along the x-z plane from an entrance trajectory of the ion beam upstream of the first magnet pair. The pair of first poles and the pair of second poles, for example, are parallel to one another.

In another example, the first coil is wound around the first yoke, and the second coil is wound around the second yoke. In another example, the first coil is wound around the pair of first elongate pole members of the first core, and the second coil is wound around the pair of second elongate pole members of the second core.

The first coil, for example, can consist of a first pair of sub-coils respectively wound around the pair of first elongate pole members, and the second coil can consist of a pair of second sub-coils respectively wound around the first pair of elongate pole members. In one example, each of the pair of first sub-coils and the pair of second sub-coils are individually electrically coupled to the current source. As such, the current source can be configured to selectively supply the current to each of the pair of first sub-coils and the pair of second sub-coils, respectively. In another example, the current source is configured to individually control the current respectively supplied to each of the pair of first sub-coils and the pair of second sub-coils. The current source, for example, can be further configured to individually control the current respectively supplied to each of the first coil and the second coil.

In one example, the ion beam comprises a scanned spot ion beam having a scan width extending along the y-axis, wherein the scanned spot ion beam has an energy of less than approximately 3 keV immediately upstream of the first magnet pair. In another example, the ion beam comprises a ribbon ion beam having a width extending along the y-axis, wherein the ribbon ion beam has an energy of less than approximately 3 keV immediately upstream of the first magnet pair.

In accordance with another example aspect, a second magnet pair is further provided and positioned downstream of the first magnet pair. The second magnet pair, for example, comprises a third core having a third yoke and a pair of third elongate members extending from the third yoke, thereby defining a third U-shape in the y-z plane extending along the x-axis. The pair of third elongate pole members, for example, define a pair of third poles at respective distal ends of the pair of third elongate members. A third coil, for example, is wound around the third core.

A fourth core, for example, is further provided having a fourth yoke and a pair of elongate fourth pole members extending from the fourth yoke. As such, a fourth U-shape is defined in the y-z plane extending along the x-axis. The pair of fourth elongate pole members, for example, define a pair of fourth poles at respective distal ends thereof, whereby the fourth pair of poles are separated from the third pair of poles by a second gap configured to pass the ion beam therethrough. A fourth coil is further wound around the fourth core.

Accordingly, the current source is further configured to selectively supply the current to the third coil and the fourth coil, respectively, wherein the pair of third poles and the pair of fourth poles are configured to further control the focus of the ion beam along the y-z plane based on the current. The exit trajectory of the ion beam along the x-z plane, for example, is thus defined downstream of the second magnet pair. As such, the pair of third poles and the pair of fourth poles are further configured to define the exit trajectory of the ion beam. In one example, the pair of third poles and the pair of fourth poles are parallel.

The first coil, for example, can be wound around the first yoke, and the second coil can be wound around the second yoke. Similarly, the third coil can be wound around the third yoke, and the fourth coil can be wound around the fourth yoke. In another example, the first coil is wound around the first of pair elongate pole members, the second coil is wound around the pair of second elongate pole members, the third coil is wound around the pair of third elongate pole members, and the fourth coil is wound around the pair of fourth elongate pole members. The present disclosure contemplates any combination discussed above, as well.

In another example, one or more current supplies are electrically coupled to one or more of the first coil, the second coil, the third coil, and the fourth coil, whereby each of the first, second, third, and fourth coils are selectively controlled. In an additional example, the first coil can be electrically coupled in series with the second coil. Similarly, the third coil can be electrically coupled in series with the fourth coil. As such, simplified control can be achieved.

With the above configurations, the exit trajectory of the ion beam, for example, can be controlled to be colinear with the entrance trajectory of the ion beam in the x-axis. Alternatively, the exit trajectory of the ion beam can be offset from the entrance trajectory of the ion beam in the x-axis.

In accordance with yet another example aspect of the disclosure, an ion implantation system is provided in which the above-described magnetic focusing apparatus can be advantageously employed. The ion implantation system, for example, can comprise an ion source configured to form an ion beam along a beam path at a first energy. The ion beam, for example, can be a spot ion beam or a ribbon ion beam that is extracted at a moderately high first energy (e.g., 30 keV-60 keV) in order to achieve desired transmission of the ion beam through the ion implantation system. A mass analyzer, for example, is provided to mass analyze the ion beam along the beam path from the ion source.

Further, in order to provide a lower energy implantation, a decelerator apparatus can be provided and configured to decelerate the ion beam along the beam path to a second energy that is lower than the first energy. For example, the ion beam can be decelerated to a lower energy of approximately 0.2 keV to 6 keV. After deceleration, for example, the ion beam is generally defined by a width along an x-axis and a height along a y-axis at an exit of the decelerator apparatus in a cartesian coordinate system. A workpiece support can be positioned downstream of the decelerator apparatus along the beam path, wherein the workpiece support is configured to selectively support a workpiece for implantation of ions thereto.

In accordance with the present disclosure, a magnetic focusing apparatus can be advantageously positioned along the beam path between the decelerator apparatus and the workpiece support, wherein the magnetic focusing apparatus is configured to focus the ion beam along the y-axis. Such a focusing can mitigate issues such as beam blow up due to the low energy of the ion beam in this area of the ion implantation system.

The magnetic focusing apparatus, for example, can comprise at least a first magnet pair, as discussed above. Alternatively, the magnetic focusing apparatus can further comprise a second magnet pair. As such, a control system can be provided and configured to control at least the current supplied to one or more of the above-described first coil and second coil to control a trajectory of the ion beam along the x-axis between an entrance and an exit of the magnetic focusing apparatus. As such, the ion beam can be advantageously focused along the y-axis, while the trajectory of the ion beam can be maintained parallel at both the entrance and the exit of the magnetic focusing apparatus. The trajectory of the ion beam, for example, can be positioned to be colinear with the beam path as the ion beam enters the magnetic focusing apparatus, or the trajectory can be skewed to provide a parallel, but offset, beam path at the exit of the magnetic focusing apparatus.

The present disclosure further contemplates various controls, such as a selective positioning of the workpiece, positioning of the workpiece support, or various other modifications to various components of the ion implantation system. The ion implantation system, for example, can further comprise a beam scanning system, wherein the beam scanning system is configured to selectively scan the ion beam along the x-axis. The beam scanning system, for example, can be further controlled to account for any offset described above by an over-scan or other modification of the scanning routine.

Thus, to the accomplishment of the foregoing and related ends, the invention comprises the features hereinafter fully described and particularly pointed out in the claims. The following description and the annexed drawings set forth in detail certain illustrative embodiments of the invention. These embodiments are indicative, however, of a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 is a schematic diagram of a conventional mass analyzer lens for focusing and mass analyzing an ion beam.

FIG. 2 is a schematic diagram illustrating focusing lens in accordance with various aspects of the present invention.

FIG. 3A is a plan view of an example of focusing in a first direction of an example focusing magnet in accordance with various aspects of the present invention.

FIG. 3B is a side view of the example of a bending in a second direction of the focusing magnet of FIG. 3A in accordance with various aspects of the present invention.

FIG. 4A is a plan view of an example of focusing in a first direction of another example focusing magnet in accordance with various aspects of the present invention.

FIG. 4B is a side view of the example of a bending in a second direction of the focusing magnet of FIG. 4A in accordance with various aspects of the present invention.

FIG. 5A is a plan view of an example of focusing in a first direction of yet another example focusing magnet in accordance with various aspects of the present invention.

FIG. 5B is a side view of the example of a bending in a second direction of the focusing magnet of FIG. 5A in accordance with various aspects of the present invention.

FIG. 6 is a side view of the example of a bending in a second direction of a focusing magnet in accordance with various aspects of the present invention.

FIG. 7A is a plan view of an example of focusing in a first direction of still another example focusing magnet in accordance with various aspects of the present invention.

FIG. 7B is a side view of the example of a bending in a second direction of the focusing magnet of FIG. 7A in accordance with various aspects of the present invention.

FIG. 8 is a schematic diagram of an example ion implantation system incorporating an example bending magnet in accordance with various aspects of the present disclosure.

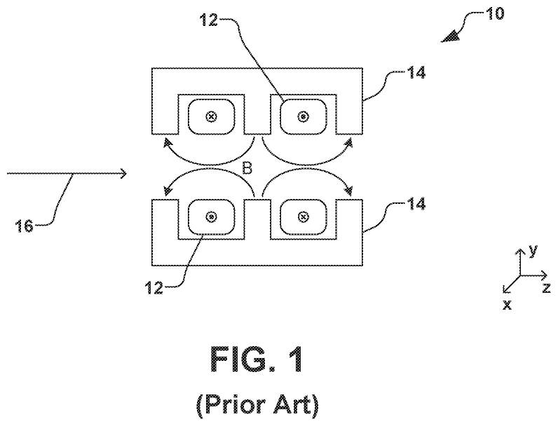

### DETAILED DESCRIPTION

The present disclosure is directed generally toward ion implantation systems and methods for implanting ions in a workpiece, and more particularly to a magnetic focusing apparatus for controlling focus and trajectory of an ion beam susceptible to beam blow up. For example, the present disclosure provides control of a height of the ion beam while maintaining a substantially constant width and angular trajectory of the ion beam.

Accordingly, the present invention will now be described with reference to the drawings, wherein like reference numerals may be used to refer to like elements throughout. It should be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details.

In order to achieve a low energy ion implantation in a workpiece using a high current or maintaining a high through-put, an ion implanter can be configured to extract ions at a moderately high energy (e.g., 20 keV-60 keV) to form an ion beam, whereby the ions are decelerated to a low energy (e.g., 0.2 keV-3 keV) just prior to the ion beam impacting the workpiece. Due to space-charge expansion (so-called “beam blow-up”), such a low energy ion beam has a tendency to increase in size, whereby control of an angle of impact with the workpiece has been conventionally difficult to attain. In a conventional high-current implanter, for example, the ion beam is scanned along a horizontal axis, whereby large heights of the ion beam in a vertical axis are present due to the space-charge expansion. Such large heights of the ion beam along the vertical axis can lead to increased particle contamination at the workpiece due to beam strike.

The present disclosure thus appreciates that ion beams tend to diverge at substantially low energies and when a current of the ion beam (also referred to as beam current) is high. For example, in a conventional ion implantation system incorporating deceleration of an ion beam, significant beam current can lead to increased space charge, whereby an increase in a height of the ion beam has an increased potential to lead to particle contamination of the ion beam. For example, when a vertical height of a horizontally-scanned ion beam increases, the increased vertical height of the ion beam can lead to the ion beam striking various components within the ion implantation system, thus leading to particle contamination of the ion beam.

Accordingly, the present disclosure is generally directed toward an improved magnetic focusing apparatus for an ion implantation system. The present disclosure, for example, is particularly suited for a low energy, high current ion implantation system configured to implant ions into a workpiece via a monochromatic ion beam (e.g., a phosphorus ion beam at approximately 3 kev). More specifically, the present disclosure is directed to a magnetic focusing apparatus having U-shaped poles for a low energy, high current ion implantation system, also referred to as a high current implanter configured to form a monochromatic ion beam.

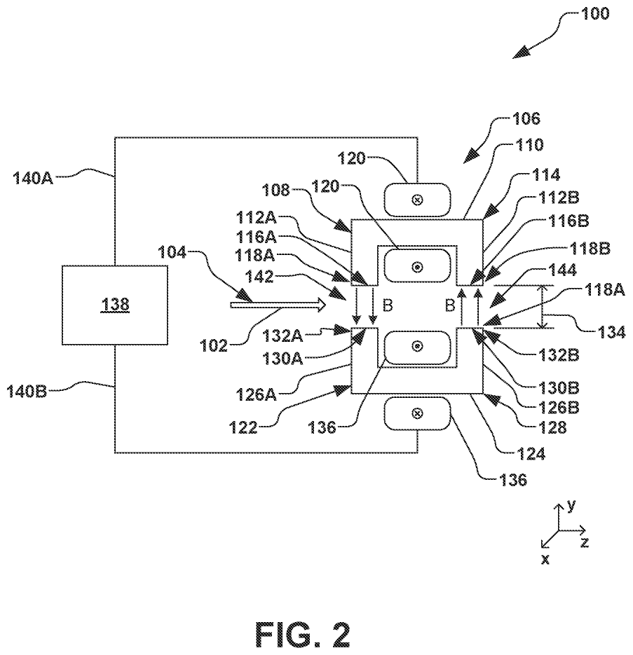

Referring now to the Figures, in accordance with various example aspects of the disclosure, a magnetic focusing apparatus 100 is provided in FIG. 2, wherein the magnetic focusing apparatus is configured for focusing an ion beam 102. The ion beam 102 for example, is illustrated in FIG. 2 as traveling substantially along the z-axis in a cartesian (x, y, z) coordinate system along a beam path 104.

The magnetic focusing apparatus 100 of FIG. 2, for example, comprises at least a first magnet pair 106. The first magnet pair 106 (also referred to as a first U-lens), for example, comprises a first core 108 having a first yoke 110 and a pair of first elongate pole members 112A, 112B extending from the first yoke 110. The first yoke 110 and pair of first elongate pole members 112A, 112B, for example, generally define a first U-shape 114. A pair of first poles 116A, 116B, for example, are further defined at respective distal ends 118A, 118B of the pair of first elongate pole members 112A, 112B. As illustrated in FIG. 2, a first coil 120 is wound around the first core 108.

The first magnet pair 106, for example, further comprises a second core 122 having a second yoke 124 and a pair of second elongate pole members 126A, 126B extending from the second yoke. Accordingly, the second yoke 124 and the pair of second elongate pole members 126A, 126B generally define a second U-shape 128. A pair of second poles 130A, 130B, for example, are further defined at respective distal ends 132A, 132B of the pair of second elongate pole members 126A, 126B. The pair of second poles 130A, 130B, for example, are separated from the pair of first poles 116A, 116B by a first gap 134 through which the ion beam 102 passes. A second coil 136, for example, is further wound around the second core 122.

The pair of first poles 116A, 116B and the pair of second poles 130A, 130B, for example, are generally planar and are parallel to one another. While not shown, the present disclosure further contemplates various architectures pair of first poles 116A, 116B and the pair of second poles 130A, 130B. For example, vertical focusing (e.g., along the y-axis) is due to a so-called magnetic pole edge effect, which is also called pole face rotation when the ion beam 102 is not normal to the pole edge. The present disclosure provides no horizontal focusing (e.g., along the x-axis), however, when the pair of first poles 116A, 116B and the pair of second poles 130A, 130B are planar and parallel to one another. As such, no pole face rotation is provided in the present magnetic focusing apparatus, whereby the present disclosure advantageously utilizes the unique effect of the parallel edges.

The present disclosure appreciates that numerous other shapes and configurations of the focusing magnet, such as varying arrangements of the poles, yoke, coil, etc. However, in all such configurations, the present disclosure provides planar and parallel poles. It shall be appreciated that all such configurations are considered to fall within the scope of the present disclosure. For example, the poles are primarily flat and parallel to each other, but the present disclosure also appreciates that some small amount of rounding of the edges can be present while still maintaining the planar and parallel poles.

As illustrated in FIG. 2, a current source 138 is further provided, wherein the current source is configured to selectively supply a current 140A, 140B to the respective first coil 120 and the second coil 136. The current source 138, for example, is configured to individually control the current 140A, 140B respectively supplied to each of the first coil 120 and the second coil 136. As such, a magnetic field B is induced between the pair of first poles 116A, 116B and the pair of second poles 130A, 130B. The magnetic field B, for example, is thus configured to focus the ion beam 102 primarily along the y-z plane based on the current 140A, 140B supplied to the respective first coil 120 and second coil 136, whereby minimal to no focusing or defocusing is provided in the x-z plane.

In the example shown in FIG. 2, the magnetic field B points downward (e.g., the −y direction) at a first entrance 142 where the ion beam 102 enters the first magnet pair 106 of the magnetic focusing apparatus 100 while the magnetic field points upward (e.g., the +y direction) at a first exit 144 of the magnetic focusing apparatus where the ion beam exits the first magnet pair (e.g., two dipole regions having opposite polarities). Unlike a traditional dipole magnet, however, the first magnet pair 106 shown in FIG. 2A, for example, comprises four poles (e.g., the pair of first elongate pole members 112A, 112B and the pair of second elongate pole members 126A, 126B), while only comprising two coils (e.g., the first coil 120 and the second coil 136). In the present example, the first coil 120 is wound around the first yoke 110, and the second coil 136 is wound around the second yoke 124.

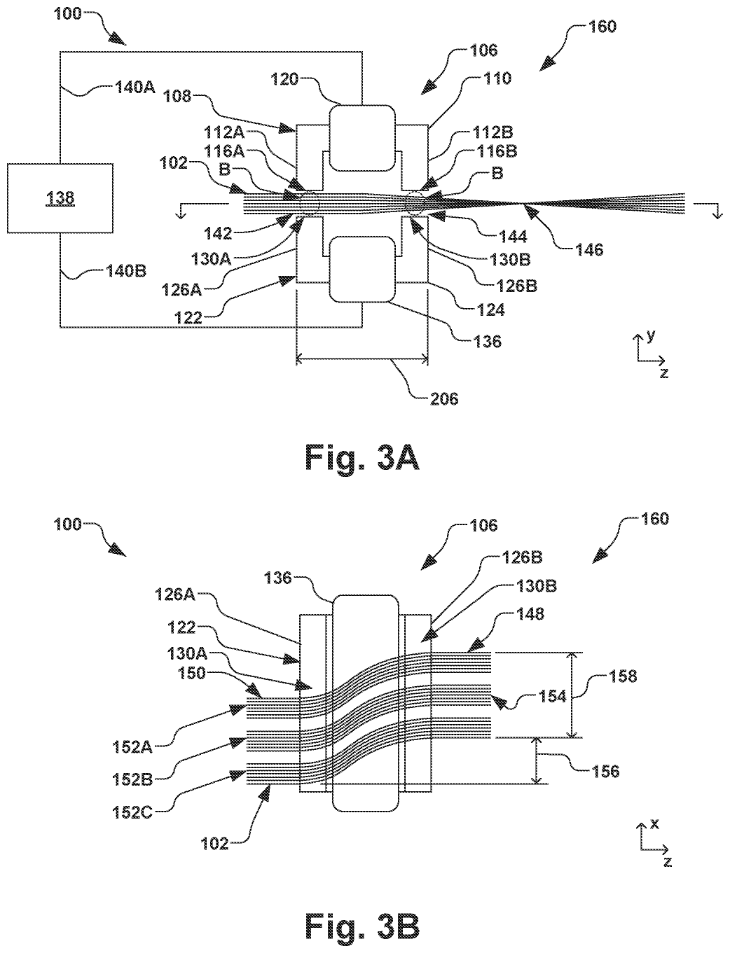

Accordingly, as illustrated in FIG. 3A, for example, the magnetic field B is thus configured to focus the ion beam 102 to a focal point 146 along the y-z plane based on the current 140A, 140B supplied to the respective first coil 120 and second coil 136. The pair of first poles 116A, 116B and the pair of second poles 130A, 130B of FIG. 3A, for example, are further configured to define an exit trajectory 148 of the ion beam 102 along the x-z plane downstream of the first magnet pair 106, as illustrated in FIG. 3B, wherein the exit trajectory of the ion beam does not angularly deviate along the x-z plane from an entrance trajectory 150 of the ion beam upstream of the first magnet pair. The first magnet pair 106, for example, provides a desirable focusing of a vertical height (e.g., in the y-direction) of the ion beam 102 downstream of the first magnet pair, while maintaining a horizontal trajectory (e.g., in the x-direction) without angular deviation.

FIG. 3B, for example, illustrates the ion beam 102 at a plurality of scanned locations 152A-152C when the ion beam is electrically or magnetically scanned upstream of the first magnet pair 106. As such, the exit trajectory 148 of the ion beam 102 at each of the scanned locations 152A-152C, for example, generally defines a scanned ion beam 154, whereby the exit trajectory of the scanned ion beam is parallel to the entrance trajectory 150 (e.g., parallel to the z-axis), while being shifted by an offset or displacement 156 along the x-z plane. In the present example, the plurality of scanned locations 152A-152C of the ion beam 102 generally defines a scan width 158 of the scanned ion beam 154, whereby the exit trajectory 148 remains parallel to the entrance trajectory 150. While the ion beam 102 is shown in just a limited number of the plurality of scanned locations 152A-152C for illustrative purposes, it shall be appreciated that the scanning of the ion beam 102 is continuous and can comprise an infinite number of scanned locations.

Similarly, as opposed to the ion beam 102 being scanned upstream of the first magnet pair 106, while not shown, the present disclosure contemplates the ion beam comprising any ribbon-shaped ion beam having a width equal to the scan width 158 along the x-z plane (e.g., along the x-axis), whereby the exit trajectory 148 is similarly not angularly offset from the entrance trajectory 150 of the ion beam. It shall be further appreciated that the entrance trajectory 150 and exit trajectory 148 of the ion beam 102, for example, is defined upstream and downstream of the first magnet pair 106 at a respective locations along the beam path 104 whereby the magnetic field B of the magnetic focusing apparatus 100 does not affect the trajectory of the ion beam at such locations. The magnetic focusing apparatus 100, for example, can be positioned downstream of a beam paralleling device, such as a corrector magnet or a so-called p-lens.

As opposed to a conventional quadrupole magnet that focuses an ion beam in two orthogonal directions, the present disclosure primarily focuses only in a single direction (e.g., the vertical direction along the y-axis). For example, fringe field effects and pole face rotations provide a focusing effect. The present disclosure, for example, contemplates a focusing effect caused by a fringe field of magnet edges (e.g., pole face rotations), whereby parallel sides of the magnet generally maintain parallelism of the ion beam 102 in the horizontal plane (e.g., along the x-axis).

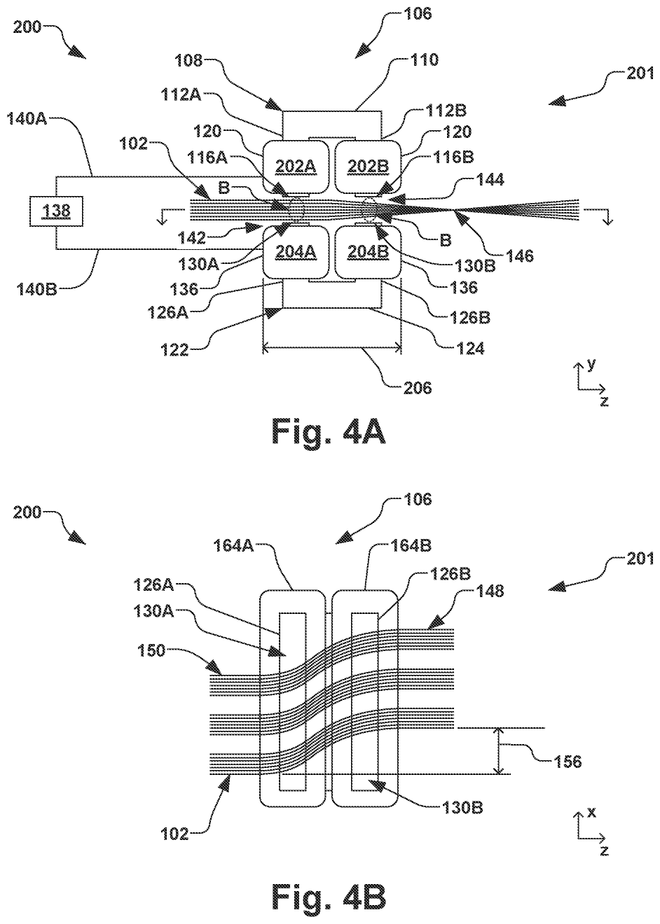

In accordance with another example of the present disclosure, FIGS. 3A-3B illustrate an example of a first configuration 160 of the magnetic focusing apparatus 100. FIGS. 4A and 4B illustrate an example of a magnetic focusing apparatus 200 in a second configuration 201. As illustrated in FIG. 4A, for example, the first coil 120 of the first magnet pair 106 is wound around the pair of first elongate pole members 112A, 112B of the first core 108, and the second coil 136 is wound around the pair of second elongate pole members 126A, 126B of the second core 122. In the present example, the first coil 120 consists of a pair of first sub-coils 202A, 202B respectively wound around the pair of first elongate pole members 112A, 112B, and the second coil 136 consists of a pair of second sub-coils 204A, 204B respectively wound around the pair of second elongate pole members 126A, 126B.

Each of the pair of first sub-coils 202A, 202B and the pair of second sub-coils 204A, 204B, for example, are electrically coupled to the current source 138, wherein the current source is configured to selectively supply the current to each of the pair of first sub-coils and the pair of second sub-coils. Similar to the example shown in FIG. 3A, the current 140A, 140B shown in FIG. 4A is respectively supplied to each of the first coil 120 and the second coil 136 (e.g., to the respective pair of first sub-coils 202A, 202B and pair of second sub-coils 204A, 204B) by the current source 138 and is configured to induce the magnetic field B in order to focus the ion beam 102 to the focal point 146 along the y-z plane. The present disclosure contemplates a length 206 (or other dimension) of the first magnet pair 106 of FIGS. 3A and 4A to vary due to the position and associated thickness of the respective first coil 120 and second coil 136 with respect to the first core 108 and second core 122. As such, in various instances, the first coil 120 shown in the first configuration 160 of the magnetic focusing apparatus 100 in FIGS. 3A-3B can be advantageous over the second configuration 201 of the magnetic focusing apparatus 200 shown in FIGS. 4A-4B, or vice-versa, depending on various space considerations along the beamline.

Again, the pair of first poles 116A, 116B and the pair of second poles 130A, 130B of FIG. 4A, for example, are further configured to define the exit trajectory 148 of the ion beam 102 along the x-z plane downstream of the first magnet pair 106, as illustrated in FIG. 4B, wherein the exit trajectory 148 of the ion beam 102 does not angularly deviate along the x-z plane from the entrance trajectory 150 of the ion beam upstream of the first magnet pair.

In another example, the present disclosure further contemplates each of the pair of first sub-coils 202A, 202B and the pair of second sub-coils 204A, 204B to be individually electrically coupled to the current source 138. As such, the current source 138 can be configured to selectively control and/or vary the respective current(s) supplied to each of the pair of first sub-coils and the pair of second sub-coils, respectively.

The present disclosure contemplates the offset or displacement 156 of low-energy ion beams 102 along the x-axis illustrated in FIGS. 3B and 4B, for example, being compensated by an offset configuration or control of various components of an ion implantation system. For example, the offset or displacement 156 can be compensated for by increasing a width of a ribbon-shaped beam, an over-scan of a scanned ion beam, or variably positioning a workpiece downstream of the respective magnetic focusing apparatus to accommodate the offset of the ion beam with respect to the x-axis, as will be further appreciated infra.

The present disclosure appreciates, however, that some architectures of various ion implantation systems may find it impractical to compensate for the offset or displacement 156 by over-scanning or workpiece positioning, such as instances where the ion beam is proximate to the coil or when design constraints dimensionally limit the beam path. For example, offsetting a position of the workpiece may not be an ideal in some instances, as various conditions of operation of the ion implantation system (e.g., various implant species, energies, etc.) may dictate various focusing requirements and/or necessitate various other offsets of the workpiece.

Thus, in accordance with another example, the present disclosure further contemplates providing two magnet pairs positioned in order to compensate for the offset or displacement discussed above for low-energy ion beams. Such a configuration of two magnet pairs, for example, can provide a desired vertical focusing strength while returning the low-energy beam to its original horizontal position, thus generally canceling the offset or displacement of the ion beam discussed above.

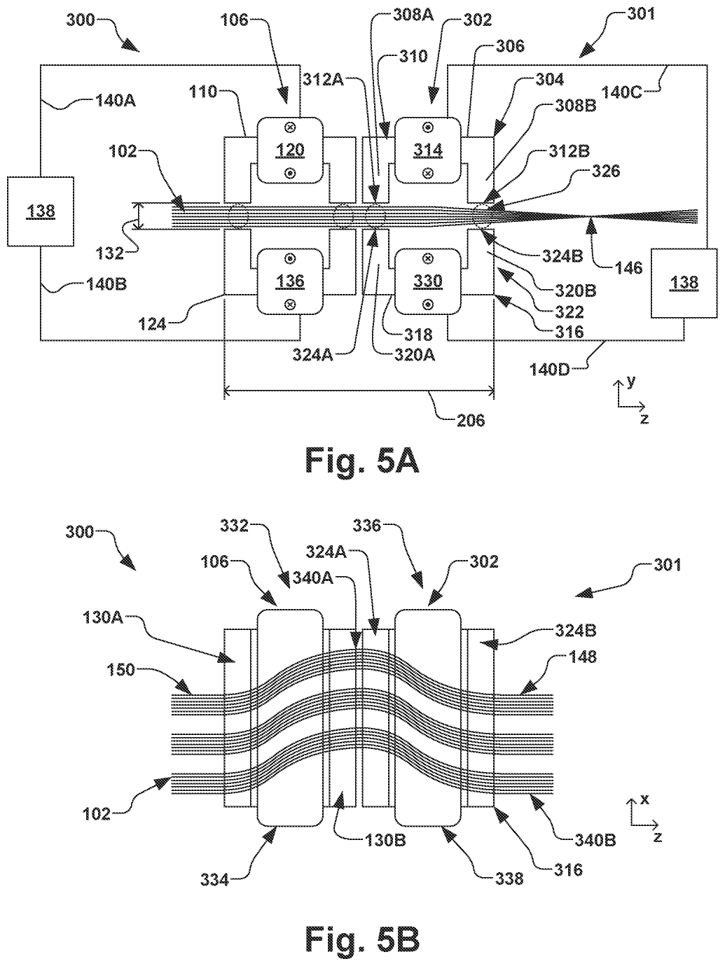

In accordance with another example aspect of the present disclosure, a magnetic focusing apparatus 300 having a third configuration 301 of the is illustrated in FIGS. 5A-5B, wherein a second magnet pair 302 is positioned downstream of the first magnet pair 106. The second magnet pair 302, for example, comprises a third core 304 having a third yoke 306 and a pair of third elongate members 308A, 308B extending from the third yoke. As such, a third U-shape 310 is defined in the y-z plane extending along the x-axis. The pair of third elongate pole members 308A, 308B, for example, further define a pair of third poles 312A, 312B at respective distal ends thereof. Furthermore, in the present example, a third coil 314 is wound around the third core 304.

The second magnet pair 302, for example, further comprises a fourth core 316 having a fourth yoke 318 and a pair of fourth elongate pole members 320A, 320B extending from the fourth yoke, thereby defining a fourth U-shape 322 in the y-z plane extending along the x-axis. The pair of fourth elongate pole members 320A, 320B, for example, define a pair of fourth poles 324A, 324B at respective distal ends thereof, whereby the pair of fourth poles are separated from the pair of third poles 312A, 312B by a second gap 326. The second gap 326, for example, is further configured to pass the ion beam 102 therethrough. In the present example, the second gap 326 is equal to the first gap 132 described above.

A fourth coil 330, for example, is further wound around the fourth core 316, wherein the current source is further configured to selectively supply the current 140C, 140D to the third coil 314 and the fourth coil 330, respectively, wherein the pair of third poles 312A, 312B and the pair of fourth poles 324A, 324B are configured to further control the focus of the ion beam along the y-z plane based on the current. For example, the pair of third poles 312A, 312B and the pair of fourth poles 324A, 324B are parallel to one another along the x-z plane. Further, as illustrated in FIG. 5B, the exit trajectory 148 of the ion beam 102 along the x-z plane is defined downstream of the second magnet pair 302, wherein the pair of third poles 312A, 312B and the pair of fourth poles 324A, 324B are further configured to define the exit trajectory of the ion beam. The exit trajectory 148 of the ion beam 102, for example, can be advantageously controlled to be colinear with from the entrance trajectory 150 of the ion beam along the x-axis.

As illustrated in FIGS. 5A-5B, the first coil 120 is wound around the first yoke 110, the second coil 136 is wound around the second yoke 124, the third coil 314 is wound around the third yoke 306, and the fourth coil 330 is wound around the fourth yoke 318. In one example, the first coil 120 is electrically coupled in series with the second coil 136, and the third coil 314 is electrically coupled in series with the fourth coil 330.

In one example, the first magnet pair 106 generally defines an upstream U-lens 332 and an upstream coil 334, whereby the second magnet pair 302 generally defines a downstream U-lens 336 and a downstream coil 338, as illustrated in FIG. 5B. Accordingly, the respective current 140A-140D of FIG. 5A selectively provided to the respective upstream coil 334 and downstream coil 338, for example, is selectively variable, whereby the ion beam 102 is selectively offset in a horizontal direction based on the selective variation of the upstream current and downstream current. The current source 138, for example, is contemplated as being one or more current supplies electrically coupled to one or more of the first coil 120, the second coil 136, the third coil 314, and the fourth coil 330.

Thus, the present disclosure provides for a selective variation of an upstream current (e.g., currents 140A, 140B) and a downstream current (e.g., currents 140C, 140D) associated with the respective first magnet pair 106 and second magnet pair 302. Such a selective variation, for example, is referred to as “trim”, whereby the upstream U-lens 332 and downstream U-lens 336 are configured to selectively control the horizontal position (e.g., along the x-z plane) of the ion beam as the ion beam passes through the third configuration 301 of the magnetic focusing apparatus 300 of FIGS. 5A-5B.

Conventional quadrupole magnets often used in ion implantation, for example, focus the ion beam in one axis, while the ion beam is defocused in an orthogonal axis. The present disclosure, on the other hand, provides advantageous focusing in the y-axis while maintaining a parallel trajectory of the ion beam at both an entrance and an exit of the magnetic focusing apparatus, thus ameliorating the deleterious defocusing seen in conventional quadrupole magnets. As such, in one example, the present disclosure does not significantly alter an angular trajectory of the beam along a first axis, while providing a focusing of the ion beam along a second axis.

In the magnetic focusing apparatus 300 comprising the upstream U-lens 332 downstream U-lens 336, for example, the respective coils and the poles can be similar to that shown in FIG. 2. However, the upstream and downstream U-lenses 332, 336 of FIG. 5B, for example, are utilized to first offset the ion beam 102 in a primary offset 339A (e.g., changing a trajectory of the ion beam in the +x direction) and to subsequently offset the ion beam to a secondary offset 339B (e.g., changing the trajectory of the ion beam in the −x direction), while further concurrently focusing the ion beam to the focal point 146 along the y-axis, as illustrated in FIG. 5A.

Respective positioning of primary and secondary offsets 340A, 340B of the ion beam 102, for example, can be colinear as illustrated in FIG. 5B (e.g., zero final offset of the ion beam from the entrance to the exit), or the primary and secondary offsets can be further offset from one another along the x-axis, wherein control of the respective offsets can be attained by the respective currents applied to the respective coils discussed above.

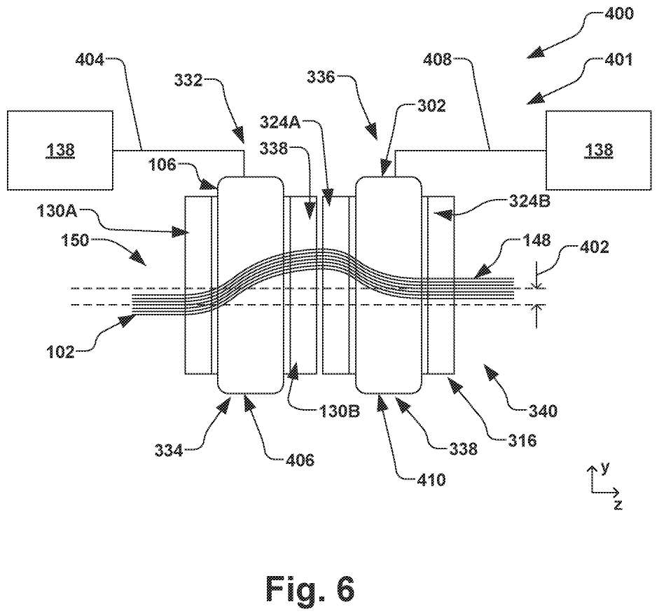

For example, FIG. 6 illustrates a magnetic focusing apparatus 400 having a fourth configuration 401, whereby a final trim offset 402 is provided by the upstream and downstream U-lenses 332, 336. For example, a first current 404 (e.g., +180 A) is provided to a first coil set 406 (e.g., the first and second coils 120, 136 of FIG. 5A), and a second current 408 (e.g., +120 A) is provided to a second coil set 410 (e.g., the third and fourth coils 314, 330), whereby a current offset (e.g., 60A in the present example) is configured to provide the trim offset of the ion beam 102 shown in FIG. 6. The trim offset 402 in the ion beam 102, for example, can be thus controlled or tuned to provide a desired position of the ion beam downstream of the second magnet pair 302. In another example, current supplied to one or more of the individual coils (e.g., one or more of the first coil 120, second coil 136, third coil 314, and fourth coil 330 of FIG. 5A) can be individually controlled, thus providing a wide range of control of the trim offset 402.

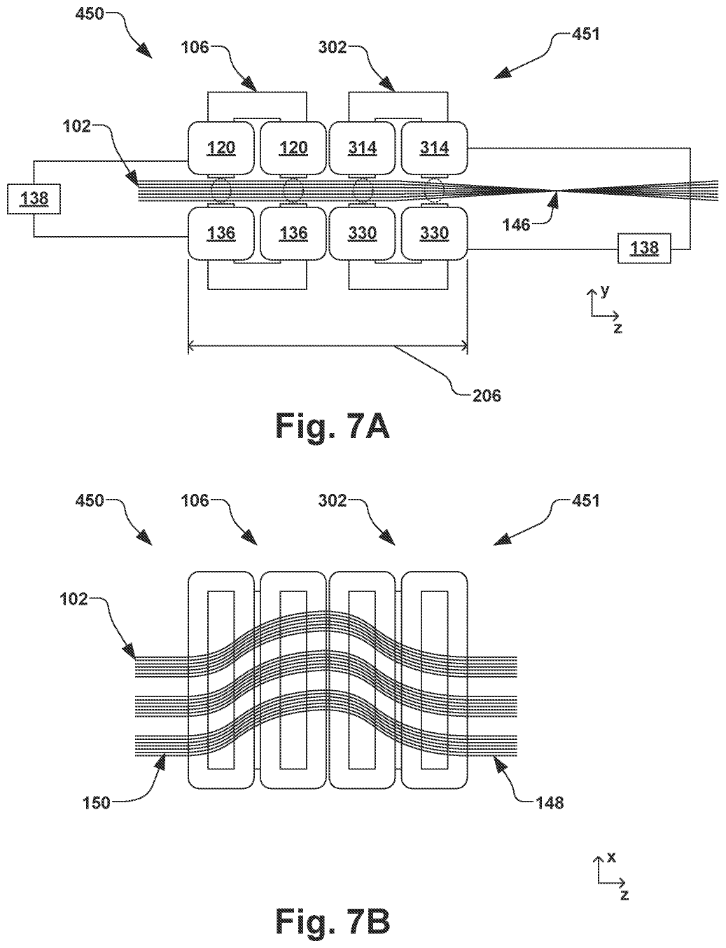

In accordance with yet another example, a magnetic focusing apparatus 450 having a fifth configuration 451 of the is illustrated in FIGS. 7A-7B, wherein the first magnet pair 106 and second magnet pair 302 are configured similar to the first magnet pair shown in FIG. 4A. As such, further control of the focusing and trajectory of the ion beam 102 can be attained in a manner similar to that discussed above. It is noted that the fifth configuration 451 of the magnetic focusing apparatus 450 illustrated in FIGS. 7A-7B may be longer than that of the third configuration 301 of the magnetic focusing apparatus 300 of FIGS. 5A-5B, whereby the footprint of the third configuration may be smaller than that of the fifth configuration.

The present disclosure thus provides a magnetic focusing apparatus 100 for focusing an ion beam along the y-axis while controlling an offset of the ion beam along the x-axis, while maintaining an angular trajectory of the ion beam in along the x-z plane. The present disclosure thus contemplates a parallel-sided dipole magnet having a small footprint, whereby strong focusing can be attained for a low-energy ion beam along the y-axis, while providing no substantial focusing along the x-axis, whereby parallelism in the x-z plane is maintained at the exit of the magnet. The present disclosure provides numerous advantages over conventional E-lens systems, such as prevention of a twisting of the ion beam due to bucking or opposing magnetic fields.

The present disclosure appreciates that the magnetic lens provided herein is particularly advantageous for a low energy ion beam, where space charge and beam blow up of the low energy ion beam can be of significant concerns along the path of the ion beam. The magnetic lens of the present disclosure, for example, is relatively weak, however, when compared to various lenses provided in conventional high energy ion implantation systems, as space charges and beam blow up are significantly less concerning in such high energy ion implantation systems.

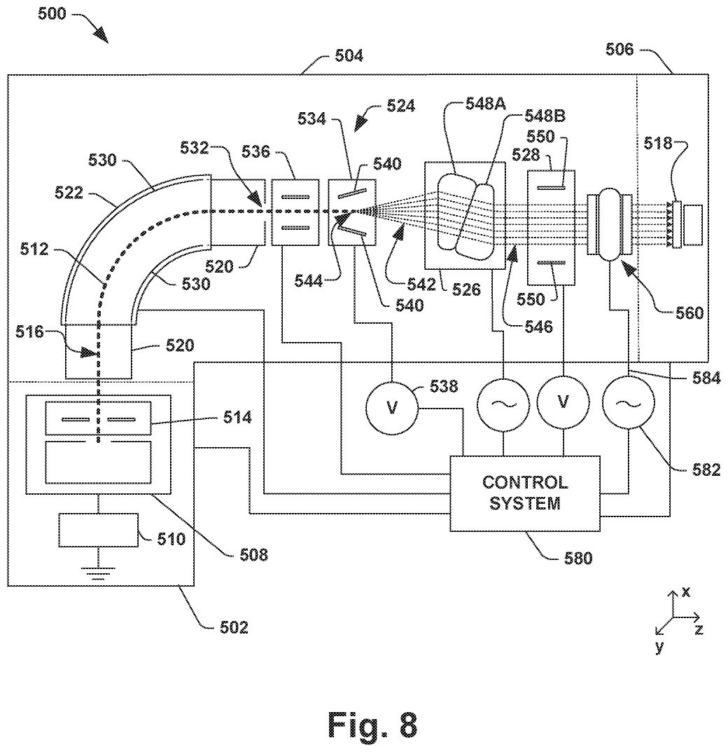

In accordance with another example aspect of the present disclosure, FIG. 8 illustrates an ion implantation system 500 comprising a terminal 502, a beamline assembly 504, and an end station 506. The terminal 502, for example, includes an ion source 508 powered by a high voltage power supply 510, wherein the ion source is configured to produce and direct an ion beam 512 to the beamline assembly 504. The ion source 508, for example, generates charged ions from a dopant material, whereby the ions are extracted from the source via an extraction assembly 514 and formed into the ion beam 512 that is subsequently directed along a beam path 516 in the beamline assembly 504 to a workpiece 218 positioned within the end station 506.

The beamline assembly 504, for example, includes a beamguide 520, a mass analyzer 522, a scanning system 524, a parallelization apparatus 526, and a deceleration apparatus 528. The mass analyzer 522, for example, is configured to have approximately a ninety-degree angle and comprises one or more magnets (not shown) that serve to establish a dipole magnetic field therein. As the ion beam 512 enters the mass analyzer 522, it is correspondingly bent by the magnetic field such that desired ions are transported down the beam path 516, while ions of an inappropriate charge-to-mass ratio are rejected. More particularly, ions having too great or too small a charge-to-mass ratio are deflected either insufficiently or exceedingly so as to be steered into side walls 530 of the mass analyzer 522 so that the mass analyzer allows those ions in the ion beam 512 that have the desired charge-to-mass ratio to pass there-through and exit through a resolving aperture 532.

The scanning system 524, for example, comprises a scanning element 534 and a focusing and/or steering element 536. The scanning system 524, for example, can comprise various known scanning mechanisms, such as demonstrated in U.S. Pat. No. 4,980,562 to Berrian et al.; U.S. Pat. No. 5,091,655 to Dykstra et al.; U.S. Pat. No. 5,393,984 to Glavish; U.S. Pat. No. 7,550,751 to Benveniste et al.; and U.S. Pat. No. 7,615,763 to Vanderberg et al., the entirety of which are hereby incorporated herein by reference. It will be understood that an ion implantation system of the type described herein may employ different types of scanning systems. For example, the present disclosure contemplates the scanning system 524 electrostatically or magnetically scanning the ion beam 512, and all such scanning systems are contemplated in the present disclosure.

Downstream of the mass analyzer 522 (e.g., an AMU magnet), the ion beam 512 comprises like-charged particles, whereby the ion beam may have a tendency to expand radially outwardly, or “blow up”, as the like-charged particles repel one another within the ion beam along the beam path 516. The present disclosure appreciates that the phenomenon of beam blow-up can be exacerbated in low energy, high current (e.g., high perveance) ion beams after the deceleration apparatus 528 (e.g., a deceleration lens), where many like-charged particles are moving in the same direction relatively slowly, and wherein there is an abundance of repulsive forces among the particles, but little particle momentum to keep the particles moving in the direction of the beam path.

Accordingly, the extraction assembly 514 of the ion implantation system 500 is generally configured such that the ion beam 512 is extracted at a moderately high energy (e.g., 20 keV-60 keV), whereby the ion beam does not blow up (e.g., the particles travel fast enough, such that there is not enough time for significant beam blow up to occur). It is generally advantageous to transfer the ion beam 512 at a relatively high energy throughout the majority of the ion implantation system 500, wherein the energy of the ion beam can be reduced as desired just prior to implantation of the ions into the workpiece 518 to promote beam containment.

In the example illustrated in FIG. 8, the scanning system 524 is configured to electrostatically scan the ion beam 512, wherein the scanning system comprises a power supply 538 coupled to scanner electrodes 540. The scanning system 524, for example, receives the ion beam 512 after being mass analyzed, at which point, the ion beam has a relatively narrow profile (e.g., a “pencil” beam in the illustrated system). A voltage waveform applied to the scanner electrodes 540 is configured to scan the ion beam 512 back and forth in the X-direction (e.g., the so-called scan direction) to spread the beam into a scanned ion beam 542 (e.g., an elongate ribbon-shaped beam). In one example, the scanned ion beam 542 has an effective X-direction width that may be at least as wide as or wider than the workpiece 518. While not shown, in a magnetic scanning system, a high current supply is connected to coils of an electromagnet, whereby the magnetic field is adjusted to scan the beam.

It shall be noted that while the ion beam is described in various examples as being a scanned spot ion beam, the ion beam can take a variety of forms and shapes, such as a so-called “ribbon beam”, a “pencil beam”, or various other ion beams, and all such ion beams are contemplated as falling within the scope of the present disclosure.

The scanned ion beam 542 is subsequently passed through the parallelization apparatus 526, whereby the parallelization apparatus causes the incoming scanned ion beam 542 having divergent rays or beamlets originating from the scan vertex 544 to be deflected into parallel rays or beamlets 546 so that implantation parameters (e.g., implant angles) are uniform across the workpiece 518. In the presently illustrated embodiment, the parallelization apparatus 526 comprises two dipole magnets 548A, 548B, wherein the dipoles are substantially trapezoidal and are oriented to mirror one another to cause the ion beam 512 (the scanned ion beam 542) to bend into a substantially “s-shape”. Alternatively or in addition, the parallelization apparatus 526, for example, can comprise various other parallelization lenses, such as a single corrector magnet or a p-lens.

Downstream of the parallelization apparatus 526, one or more stages of the deceleration apparatus 528 are provided. Examples of deceleration and/or acceleration systems are demonstrated by U.S. Pat. No. 5,091,655 to Dykstra et al. U.S. Pat. No. 6,441,382 to Huang and U.S. Pat. No. 8,124,946 to Farley et al., the entirety of which are hereby incorporated herein by reference. As previously indicated, up to this point in the ion implantation system 500, the ion beam 512 is generally transported at a relatively high energy level to mitigate the propensity for beam blow-up, which can be particularly high where beam density is elevated, such as at the resolving aperture 532, for example. Similar to the extraction assembly 514, the scanning element 534 and the focusing and steering element 536, the deceleration apparatus 528 comprises one or more electrodes 550 operable to decelerate the ion beam 512 to a low energy (e.g., 0.2 keV-3 keV).

The present disclosure appreciates that the ion beam 512 (e.g., the scanned ion beam 542), being at the low energy after passing through the deceleration apparatus 528, is at a desired energy for implantation into the workpiece 518, but is highly susceptible to the above-described beam blow up. Accordingly, the ion implantation system 500 further comprises a magnetic focusing apparatus 560. The magnetic focusing apparatus 560, for example, is contemplated as comprising any of the magnetic focusing apparatus of FIGS. 2-8.

The ion implantation system 500 further comprises a control system 580 (e.g., a control system, computer, or other control apparatus) configured to provide general or specific control of the ion implantation system. The control system 580, for example, can comprise a computer, microprocessor, etc. and is operatively coupled to one or more of the terminal 502, beamline assembly 504, and end station 506 for control of any components associated therewith. For example, the control system 580 is configured to control the generation of the ion beam 512 from the ion source 508, as well as various controls of the transport of the ion beam along the beam path 516 through the mass analyzer 522, scanning system 524, parallelization apparatus 526, deceleration apparatus 528, and magnetic focusing apparatus 560. The control system 580, for example, can further control various workpiece positioning apparatuses (not shown) to control a position of the workpiece 518 within the end station 506. Accordingly, any of these elements can be adjusted by the control system 580 to facilitate desired ion implantation parameters.

The control system 580, for example, is operably coupled to the magnetic focusing apparatus 560 and a focusing current source 582, whereby magnet control circuitry is configured to selectively control a magnitude of magnet current 584 supplied to the magnetic focusing apparatus based on a desired focus plane, an incoming trajectory, and/or a desired output trajectory of the ion beam 512.

The present disclosure, for example, is further particularly suitable for a final focusing of the ion beam 512 just prior to the ion beam impacting the workpiece 518, whereby the ion beam has a low energy immediately upstream of the final focusing, thereof. In order to compensate for displacement illustrated in FIG. 3B for low-energy ion beams, for example, the present disclosure contemplates an offset configuration of a scanning system 524, such as by providing an asymmetric scan amplitude to the scanner. The offset, for example, can be alternatively compensated for by increasing a width of a ribbon-shaped beam, an over-scan of a scanned ion beam, or variably positioning a workpiece downstream of the magnet to accommodate the offset of the ion beam with respect to the x-axis.

The present disclosure is particularly advantageous for various high current ion implantation systems having deceleration of the ion beam proximate to an end of the beamline. The present disclosure, for example, can maintain a minimal travel distance of the ion beam to the workpiece after deceleration, whereby the time and/or space for beam blow up is substantially limited.

Although the invention has been shown and described with respect to a certain preferred embodiment or embodiments, it is obvious that equivalent alterations and modifications will occur to others skilled in the art upon the reading and understanding of this specification and the annexed drawings. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more other features of the other embodiments as may be desired and advantageous for any given or particular application.

What is claimed is:

1. A magnetic focusing apparatus for focusing an ion beam, the ion beam traveling substantially in the z-axis in a cartesian coordinate system along a beam path, the magnetic focusing apparatus comprising:
a first magnet pair comprising:
a first core having a first yoke and a pair of first elongate pole members extending from the first yoke, thereby defining a first U-shape in the y-z plane extending along the x-axis, the pair of first elongate pole members defining a pair of first poles at respective distal ends thereof;
a first coil wound around the first core;
a second core having a second yoke and a pair of second elongate pole members extending from the second yoke, thereby defining a second U-shape in the y-z plane extending along the x-axis, the pair of second elongate pole members defining a pair of second poles at respective distal ends thereof, whereby the pair of second poles are separated from the pair of first poles by a first gap configured to pass the ion beam therethrough; and
a second coil wound around the second core; and
a current source configured to selectively supply a current to the first coil and the second coil, respectively, wherein the pair of first poles and the pair of second poles are configured to control a focus of the ion beam along the y-z plane based on the current, and wherein the pair of first poles and the pair of second poles are further configured to define an exit trajectory of the ion beam along the x-z plane downstream of the first magnet pair, and wherein the exit trajectory of the ion beam does not angularly deviate along the x-z plane from an entrance trajectory of the ion beam upstream of the first magnet pair.

2. The magnetic focusing apparatus of claim 1, wherein the first coil is wound around the first yoke, and wherein the second coil is wound around the second yoke.

3. The magnetic focusing apparatus of claim 2, wherein the first coil is wound around the pair of first elongate pole members of the first core, and wherein the second coil is wound around the pair of second elongate pole members of the second core.

4. The magnetic focusing apparatus of claim 3, wherein the first coil consists of a pair of first sub-coils respectively wound around the pair of first elongate pole members, and wherein the second coil consists of a pair of second sub-coils respectively wound around the pair of second elongate pole members.

5. The magnetic focusing apparatus of claim 4, wherein each of the pair of first sub-coils and the pair of second sub-coils are individually electrically coupled to the current source, wherein the current source is configured to selectively supply the current to each of the pair of first sub-coils and the pair of second sub-coils, respectively.

6. The magnetic focusing apparatus of claim 5, wherein the current source is configured to individually control the current respectively supplied to each of the pair of first sub-coils and the pair of second sub-coils.

7. The magnetic focusing apparatus of claim 1, wherein the current source is configured to individually control the current respectively supplied to each of the first coil and the second coil.

8. The magnetic focusing apparatus of claim 1, wherein the ion beam comprises a scanned spot ion beam having a scan width extending along the x-axis, wherein the scanned spot ion beam has an energy of less than approximately 3 keV immediately upstream of the first magnet pair.

9. The magnetic focusing apparatus of claim 1, wherein the ion beam comprises a ribbon-shaped ion beam having a width extending along the x-axis, wherein the ribbon ion beam has an energy of less than approximately 3 keV immediately upstream of the first magnet pair.

10. The magnetic focusing apparatus of claim 1, wherein the pair of first poles and the pair of second poles are parallel to one another along the x-z plane.

11. The magnetic focusing apparatus of claim 1, further comprising:
a second magnet pair positioned downstream of the first magnet pair, the second magnet pair comprising:
a third core having a third yoke and a pair of third elongate members extending from the third yoke, thereby defining a third U-shape in the y-z plane extending along the x-axis, the pair of third elongate pole members defining a pair of third poles at respective distal ends thereof;
a third coil wound around the third core;
a fourth core having a fourth yoke and a pair of fourth elongate pole members extending from the fourth yoke, thereby defining a fourth U-shape in the y-z plane extending along the x-axis, the pair of fourth elongate pole members defining a pair of fourth poles at respective distal ends thereof, whereby the pair of fourth poles are separated from the pair of third poles by a second gap configured to pass the ion beam therethrough; and
a fourth coil wound around the fourth core, wherein the current source is further configured to selectively supply the current to the third coil and the fourth coil, respectively, wherein the pair of third poles and the pair of fourth poles are configured to further control the focus of the ion beam along the y-z plane based on the current, wherein the exit trajectory of the ion beam along the x-z plane is defined downstream of the second magnet pair, and wherein the pair of third poles and the pair of fourth poles are further configured to define the exit trajectory of the ion beam.

12. The magnetic focusing apparatus of claim 11, wherein the pair of third poles and the pair of fourth poles are parallel along the x-z plane.

13. The magnetic focusing apparatus of claim 11, wherein the first coil is wound around the first yoke, wherein the second coil is wound around the second yoke, wherein the third coil is wound around the third yoke, and wherein the fourth coil is wound around the fourth yoke.

14. The magnetic focusing apparatus of claim 11, wherein the first coil is wound around the pair of first elongate pole members, wherein the second coil is wound around the pair of second elongate pole members, wherein the third coil is wound around the pair of third elongate pole members, and wherein the fourth coil is wound around the pair of fourth elongate pole members.

15. The magnetic focusing apparatus of claim 11, further comprising one or more current supplies electrically coupled to one or more of the first coil, the second coil, the third coil, and the fourth coil.

16. The magnetic focusing apparatus of claim 11, wherein the first coil is electrically coupled in series with the second coil, and wherein the third coil is electrically coupled in series with the fourth coil.

17. The magnetic focusing apparatus of claim 11, wherein the exit trajectory of the ion beam is colinear with from the entrance trajectory of the ion beam in the x-axis.

18. The magnetic focusing apparatus of claim 11, wherein the exit trajectory of the ion beam is offset from the entrance trajectory of the ion beam in the x-axis.

19. An ion implantation system comprising:
an ion source configured to form an ion beam along a beam path at a first energy;
a mass analyzer configured to mass analyze the ion beam along the beam path from the ion source;
a decelerator apparatus configured to decelerate the ion beam along the beam path to a second energy that is lower than the first energy, wherein the ion beam is generally defined by a width along an x-axis and a height along a y-axis at an exit of the decelerator apparatus in a cartesian coordinate system;
a workpiece support positioned downstream of the decelerator apparatus along the beam path, wherein the workpiece support is configured to selectively support a workpiece;
a magnetic focusing apparatus positioned along the beam path between the decelerator apparatus and the workpiece support, wherein the magnetic focusing apparatus is configured to focus the ion beam along the y-axis, wherein the magnetic focusing apparatus comprises:
a first magnet pair comprising:
a first U-shaped core having a pair of first elongate poles disposed at respective distal ends of the first U-shaped core, wherein the pair of first elongate poles extend along the x-axis;
a first coil wound around the first U-shaped core;
a second U-shaped core having a pair of second elongate poles facing the pair of first elongate poles, wherein the pair of second elongate poles are disposed at respective distal ends of the second U-shaped core, wherein the pair of second elongate poles extend along the x-axis, and whereby the pair of first elongate poles and pair of second elongate poles are separated by a first gap along the y-axis, wherein the beam path passes through the first gap; and
a second coil wound around the second U-shaped core;
a current source configured to selectively supply a current to the first coil and the second coil, respectively; and
a control system configured to control at least the current supplied to one or more of the first coil and the second coil to control a trajectory of the ion beam along the x-axis between an entrance and an exit of the magnetic focusing apparatus and to focus the ion beam in along the y-axis, wherein the trajectory is of the ion beam is parallel at the entrance and the exit of the magnetic focusing apparatus.

20. The ion implantation system of claim 19, wherein the first energy ranges between approximately 20 keV and approximately 60 keV, and wherein the second energy ranges between approximately 0.2 keV and approximately 3 keV.
